(19) United States
(12) Patent Application Publication
(10) Pub. No.: US 2014/0264364 A1
(43) Pub. Date: Sep. 18, 2014

(54) SEMICONDUCTOR DEVICE

(71) Applicant: FUJITSU LIMITED, Kawasaki-shi (JP)

(72) Inventor: Masahito KANAMURA, Isehara (JP)

(73) Assignee: FUJITSU LIMITED, Kawasaki-shi (JP)

(21) Appl. No.: 14/105,524

(22) Filed: Dec. 13, 2013

(30) Foreign Application Priority Data
Mar. 18, 2013 (JP) 2013-055667

(51) Int. Cl. H01L 29/778; H01L 29/20

(52) U.S. Cl. CPC H01L 29/7787; H01L 29/2003
USPC 257/76; 257/194

(57) ABSTRACT

A semiconductor device includes a substrate, a first semiconductor layer formed on the substrate, a second semiconductor layer formed on the first semiconductor layer, a first insulation layer formed on the second semiconductor layer, the first insulation layer being formed of a material that includes SiO₂, a second insulation layer formed on the first insulation layer, the second insulation film being formed of a material that includes one or more selected from Al₂O₃, ZrO₂, Ta₂O₅, Ga₂O₃, and HfO₂, and a gate electrode formed on the second insulation layer.

### CROSS-REFERENCE TO RELATED APPLICATIONS

This application is based upon and claims the benefit of priority to Japanese Patent Application No. 2013-055667 filed on Mar. 18, 2013, the entire contents of which are herein incorporated by reference.

### FIELD

A certain aspect of the embodiments discussed herein relates to a semiconductor device.

### BACKGROUND

A material that is GaN, AlN, InN, or the like that is a nitride semiconductor or a crystal thereof has a broad band gap and has been used in a high power electronic device, a short wavelength light-emitting device, or the like. Among these, a technique has been developed for a field-effect transistor (FET), in particular, a high electron mobility transistor (HEMT), as a high power device (for example, Japanese Patent Application Publication No. 2002-359256). An HEMT using such a nitride semiconductor is used in a high power/high efficiency amplifier, a high power switching device, or the like.

An HEMT using a nitride semiconductor is such that an aluminum gallium nitride/gallium nitride (AlGaN/GaN) heterostructure is formed on a substrate and a GaN layer is an electron transit layer. Here, for the substrate, a substrate is used that is formed of sapphire, silicon carbide (SiC), gallium nitride (GaN), silicon (Si), or the like.

The band gap of GaN is 3.4 eV, is greater than the band gap (1.1 eV) of Si or the band gap (1.4 eV) of GaAs, and has a high breakdown voltage. Furthermore, it is possible to obtain a high saturated electron velocity, a high voltage operation, and high power, and hence, it is possible to be used for a high efficiency switching element, a high electric strength device in an electric vehicle, or the like. Moreover, a device with an insulating gate structure provided by an insulating film under a gate electrode is also disclosed in order to suppress a leakage current in a transistor (for example, Japanese Patent Application Publication No. 2010-199481).

Meanwhile, a normally off operation is desired in a power switching element so that no electric current flows in a semiconductor element in the case where a gate voltage is 0 V. For such a normally off operation, it is necessary to shift a gate threshold voltage to a positive side, and a study of a structure provided with a p-GaN cap layer or a structure formed with a gate recess is being conducted. However, in the case of a structure provided with a p-GaN cap layer, a problem occurs that crystal growth is difficult, and in the case of a structure formed with a gate recess, a problem occurs that etching damage or the like is readily caused and control of the depth of the gate recess is difficult.

Hence, for a semiconductor device such as a field-effect transistor using a nitride semiconductor such as GaN for a semiconductor material, a semiconductor device is desired that is capable of being readily fabricated, conducts a normally off operation, and has a high uniformity.

### SUMMARY

According to an aspect of the embodiments, a semiconductor device includes a substrate, a first semiconductor layer formed on the substrate, a second semiconductor layer formed on the first semiconductor layer, a first insulation layer formed on the second semiconductor layer, the first insulation layer being formed of a material that includes SiO₂, a second insulation layer formed on the first insulation layer, the second insulation film being formed of a material that includes one or more selected from Al₂O₃, ZrO₂, Ta₂O₅, Ga₂O₃, and HfO₂, and a gate electrode formed on the second insulation layer.

The object and advantages of the invention will be realized and attained by means of the elements and combinations particularly pointed out in the claims.

It is to be understood that both the forgoing general description and the following detailed description are exemplary and explanatory and are not restrictive of the invention.

### BRIEF DESCRIPTION OF THE DRAWINGS

FIG. 1 is a structural diagram of a semiconductor device in a first embodiment;

FIG. 2A, FIG. 2B, and FIG. 2C are illustration diagrams (1) of a first insulation layer and a second insulation layer;

FIG. 3 is an illustration diagram (2) of a first insulation layer and a second insulation layer;

FIG. 4 is an illustration diagram (3) of a first insulation layer and a second insulation layer;

FIG. 5A, FIG. 5B, and FIG. 5C are process diagrams (1) of a fabrication method of a semiconductor device in the first embodiment;

FIG. 6A, FIG. 6B, and FIG. 6C are process diagrams (2) of a fabrication method of a semiconductor device in the first embodiment;

FIG. 7A and FIG. 7B are process diagrams (3) of a fabrication method of a semiconductor device in the first embodiment;

FIG. 8 is a structural diagram of a semiconductor device in a second embodiment;

FIG. 9A, FIG. 9B, and FIG. 9C are process diagrams (1) of a fabrication method of a semiconductor device in the second embodiment;

FIG. 10A, FIG. 10B, and FIG. 10C are process diagrams (2) of a fabrication method of a semiconductor device in the second embodiment;

FIG. 11A and FIG. 11B are process diagrams (3) of a fabrication method of a semiconductor device in the second embodiment;

FIG. 12 is a structural diagram of a semiconductor device in a third embodiment;

FIG. 13 is a structural diagram of a semiconductor device in a fourth embodiment;

FIG. 14 is a structural diagram of a semiconductor device in a fifth embodiment;

FIG. 15 is an illustration diagram of a discrete-packaged semiconductor device in a sixth embodiment;

FIG. 16 is a circuit diagram of a power supply device in the sixth embodiment; and

FIG. 17 is a structural diagram of a high power amplifier in the sixth embodiment.

### DESCRIPTION OF EMBODIMENT(S)

Some embodiments will be described with reference to the drawings below. Here, an identical reference numeral is attached to the same member or the like, and a duplicate description(s) thereof will be omitted.

### First Embodiment

### Semiconductor Device

A semiconductor device according to a first embodiment will be described based on FIG. 1.

A semiconductor device according to the present embodiment is such that an electron transit layer 12 formed of i-GaN that is a first semiconductor layer and an electron supply layer 13 formed of AlGaN that is a second semiconductor layer are laminated and formed on a substrate 11. An inter-element separation area 21 is formed on a part of the electron supply layer 13 and the electron transit layer 12. An insulation film 30 is formed on the electron supply layer 13 in an area other than an area for forming a source electrode 42 and a drain electrode 43. An opening 30a is formed on this insulation film 30 in such a manner that a surface of the electron supply layer 13 is exposed in an area for forming a gate electrode 41. Furthermore, the first semiconductor layer and the second semiconductor layer are formed of nitride semiconductors in the present embodiment.

Furthermore, a first insulation layer 31 and a second insulation layer 32 are laminated and formed on the electron supply layer 13 and the insulation film 30 at the opening 30a of the insulation film 30. The gate electrode 41 is formed on the second insulation layer 32 in an area of the insulation film 30 where the opening 30a has been formed. The source electrode 42 and the drain electrode 43 are formed on the electron supply layer 13. Furthermore, a protection insulation film 33 is formed on the second insulation layer 32 or the like.

In the present embodiment, a two dimensional electron gas (2DEG) 12a is produced in the electron transit layer 12 and near an interface between the electron transit layer 12 and the electron supply layer 13. However, in the present embodiment, 2DEG 12a is eliminated directly below the gate electrode 41 for the reason described below, and hence, it is possible to attain normally off.

In the present embodiment, the first insulation layer 31 and the second insulation layer 32 are formed of mutually different oxides. Specifically, the first insulation layer 31 is formed of a material that includes SiO₂, HfO₂, or the like. In the case where the first insulation layer 31 is formed of a material that includes SiO₂, the second insulation layer 32 is formed of a material that includes one or two selected from Al2O₃, ZrO₂, Ta₂O₅, Ga₂O₃, HfO₂, and the like. Furthermore, in the case where the first insulation layer 31 is formed of a material that includes HfO₂, the second insulation layer 32 is formed of a material that includes one or more selected from Al2O₃, ZrO₂, Ta₂O₅, Ga₂O₃, and the like.

Here, in the case where the first insulation layer 31 is formed of a material that includes SiO₂, it is preferable for the second insulation layer 32 to be formed of a material that includes Al₂O₃ or HfO₂. Furthermore, in the case where the first insulation layer 31 is formed of a material that includes HfO₂, it is preferable for the second insulation layer 32 to be formed of a material that includes Al₂O₃.

Furthermore, the insulation film 30 is formed of an oxide or a nitride, and specifically, is formed of a material that includes SiO₂, SiN, or the like. In the present embodiment, the insulation film 30 is formed of SiN. Here, the insulation film 30 in the present embodiment may be described as a third insulation layer.

Furthermore, the protection insulation film 33 is formed of an insulation material such as an oxide or a nitride, and in the present embodiment, the protection insulation film 33 is formed of a material that includes SiO₂, SiN, or the like.

(First Insulation Layer 31 and Second Insulation Layer 32)

Next, the first insulation layer 31 and the second insulation layer 32 in the present embodiment will be described. As illustrated in FIG. 2A, FIG. 2B, and FIG. 2C, a sample is fabricated by forming an insulation layer on a nitride semiconductor layer 81 and forming an electrode 85 on this insulation layer, and a relationship between voltage and capacitance is measured for the fabricated sample. Here, the nitride semiconductor layer 81 corresponds to the electron transit layer 12 and the electron supply layer 13.

A sample 2A illustrated in FIG. 2A is such that an oxygen plasma treatment and a heat treatment in an oxygen atmosphere are conducted for a nitride semiconductor layer 81 formed of AlGaN and subsequently an Al₂O₃ film 82 is film-formed on the nitride semiconductor layer 81 to have a thickness of about 40 nm. Here, an electrode 85 is formed on the Al₂O₃ film 82. A heat treatment is conducted for the sample 2A at a temperature of 600° C. in atmospheric air, and thereby, a surface of the nitride semiconductor layer 81 is oxidized to form an oxide film 83 of AlOₓ, GaOₓ, InOₓ, or the like. Hence, the Al₂O₃ film 82 is formed on this oxide film 83.

A sample 2B illustrated in FIG. 2B is such that a natural oxidation film on a surface of a nitride semiconductor layer 81 formed of AlGaN is eliminated by hydrofluoric acid or the like and subsequently an Al₂O₃ film 82 is film-formed on the nitride semiconductor layer 81 to have a thickness of about 40 nm. Here, an electrode 85 is formed on the Al₂O₃ film 82. Therefore, in the sample 2B, the Al₂O₃ film 82 is formed directly on the nitride semiconductor layer 81.

A sample 2C illustrated in FIG. 2C is such that an SiO₂ film 84 with a thickness of about 5 nm is film-formed on a nitride semiconductor layer 81 formed of AlGaN, an Al₂O₃ film 82 with a thickness of about 35 nm is film-formed on the SiO₂ film 84, and a heat treatment is conducted at a temperature of about 600° C. Here, an electrode 85 is formed on the Al₂O₃ film 82.

For such fabricated samples 2A, 2B, and 2C, a result of measuring a relationship between voltage and capacitance (capacitance-voltage (CV) curve) is illustrated in FIG. 3. Specifically, this CV curve is measured by using the electrode 85 and a not-illustrated electrode formed around the electrode 85 and on the nitride semiconductor layer 81. As illustrated in FIG. 3, a flat band of the sample 2A is shifted to a negative side with respect to the sample 2B and a flat band of the sample 2C is shifted to a positive side with respect to the sample 2B. Hence, a structure as illustrated in the sample 2C is applied to a semiconductor device, and thereby, it is possible to attain normally off readily. Here, as a SiO₂ film is formed instead of the Al₂O₃ film in the sample 2B illustrated in FIG. 2B, a shift of a flat band to a positive side is not confirmed. Hence, it is considered that this shift of a flat band to a positive side is caused by forming the Al₂O₃ film 82 on the SiO₂ film 84 and conducting a heat treatment.

Herein, the reason why the CV curve for the sample 2C is shifted to a positive side will be described based on FIG. 4 in more detail. It is considered that after the SiO₂ film 84 is film-formed on the nitride semiconductor layer 81 as illustrated in FIG. 4(a) and the Al₂O₃ film 82 is film-formed as illustrated in FIG. 4(b), a heat treatment is conducted and thereby oxygen ions move from the Al₂O₃ film 82 to the SiO₂ film 84. Thus, oxygen ions move from the Al₂O₃ film 82 to the SiO₂ film 84, and thereby, a dipole is formed at an interface between the Al₂O₃ film 82 and the SiO₂ film 84. This dipole is such that a side of the Al₂O₃ film 82 is positive and a side of the SiO₂ film 84 is negative, and it is possible to reduce or eliminate 2DEG in the case where 2DEG is formed on the nitride semiconductor layer 81 because a side of the SiO₂ film 84 is negative. Hence, a structure illustrated in the sample 2C is applied to an area directly below the gate electrode 41 and thereby it is possible to reduce or eliminate 2DEG directly below the gate electrode 41 so that it is possible to attain normally off in a semiconductor device readily.

Meanwhile, a material is selected to move oxygen ions from one of two kinds of oxide films to the other when conducting a heat treatment or the like and the selected material is laminated, so that it is possible to produce such a dipole. For example, when, in regard to the density of oxygen of two kinds of oxide films, one of them has a high density and the other is a material with a low density, it is possible to produce a dipole by conducting a heat treatment or the like. When a combination of such materials was studied specifically, the following observation could be obtained. That is, an observation could be obtained that a dipole is readily generated when one insulation film is formed of SiO₂ and the other insulation film is formed of Al₂O₃, ZrO₂, Ta₂O₅, Ga₂O₃, or HfO₂. Furthermore, an observation could be obtained that a dipole is readily generated when one insulation film is formed of HfO₂ and the other insulation film is formed of Al₂O₃, ZrO₂, Ta₂O₅, or Ga₂O₃.

Therefore, the first insulation layer 31 is formed of a material that includes SiO₂ and the second insulation layer 32 is formed of a material that includes one or more selected from Al₂O₃, ZrO₂, Ta₂O₅, Ga₂O₃, HfO₂, and the like, so that it is possible to attain normally off. Among these, it is more preferable for the first insulation layer 31 to be formed of a material that includes SiO₂ and for the second insulation layer 32 to be formed of a material that includes Al₂O₃, HfO₂, or the like.

Furthermore, the first insulation layer 31 is formed of a material that includes HfO₂ and the second insulation layer 32 is formed of a material that includes one or more selected from Al₂O₃, ZrO₂, Ta₂O₅, Ga₂O₃, and the like, so that it is possible to attain normally off. Among these, it is more preferable for the first insulation layer 31 to be formed of a material that includes HfO₂ and for the second insulation layer 32 to be formed of a material that includes Al₂O₃ or the like.

Here, it is preferable for a film thickness of the first insulation layer 31 to be 30 nm or less, and further, it is preferable to be 20 nm or less, in order to obtain the effect of the present embodiment. Furthermore, although it is possible to obtain the effect of the present embodiment as long as the first insulation layer 31 is formed, it is preferable for a film thickness of the first insulation layer 31 to be 2 nm or more. That is because if the first insulation layer 32 is too thick, an influence of a produced dipole is reduced, and if it is too thin, it is not possible to produce a dipole sufficient to attain normally off.

(Fabrication Method of a Semiconductor Device)

Next, a fabrication method of a semiconductor device in the present embodiment will be described based on FIG. 5A, FIG. 5B. FIG. 5C, FIG. 6A, FIG. 6B, and FIG. 6C, FIG. 7A, and FIG. 7B.

First, as illustrated in FIG. 5A, a non-illustrated buffer layer that provides a semiconductor layer, an electron transit layer 12, and an electron supply layer 13 are epitaxially grown and formed in order on a substrate 11 based on a metal organic vapor phase epitaxy (MOVPE) method. Here, a structure with a cap layer formed on the electron supply layer 13 may be provided according to need. It is possible to form a cap layer based on, for example, n-GaN doped with an impurity element such as Si.

For the substrate 11, it is possible to use a substrate of Si, sapphire, SiC, GaN, AlN, or the like.

The electron transit layer 12 is a layer that provides a first semiconductor layer and is made of intentionally undoped GaN with a thickness of about 3 μm.

The electron supply layer 13 is a layer that provides a second semiconductor layer and is made of intentionally undoped Al_{0.25}Ga_{0.75}N with a thickness of about 20 nm. Here, n-type doped with an impurity element such as Si may be used for the electron supply layer 13. Thereby, 2DEG 12a is produced in the electron transit layer 12 and near an interface between the electron transit layer 12 and the electron supply layer 13.

For MOVPE in the present embodiment, trimethylgallium (TMG) as a raw material gas for Ga, trimethylaluminum (TMA) as a raw material for Al, and ammonia (NH₃) as a raw material for N are used, while monosilane (SiH₄) or the like as a raw material for Si is used. Here, these raw material gases are supplied to a reactor of an MOVPE device while hydrogen (H₂) is a carrier gas.

Then, as illustrated in FIG. 5B, an inter-element separation area 21 is formed on the formed semiconductor layer. Specifically, a photoresist is applied onto the electron supply layer 13 and light exposure and development thereof are conducted by a light exposure device, so that a non-illustrated resist pattern is formed that has an aperture in an area for forming the inter-element separation area 21. Subsequently, the inter-element separation area 21 is formed by dry etching using a chlorine-based gas or an ion implantation method. After the inter-element separation area 21 is formed, the resist pattern is eliminated by an organic solvent or the like.

Then, as illustrated in FIG. 5C, a source electrode 42 and a drain electrode 43 are formed that contact a semiconductor layer such as the electron supply layer 13. Specifically, a photoresist is applied onto the electron supply layer 13 and light exposure and development thereof are conducted by a light exposure device, so that a non-illustrated resist pattern is formed that has an aperture in an area for forming the source electrode 42 and the drain electrode 43. Subsequently, a laminated metal film of Ti/Al is film-formed by vacuum deposition and dipped in an organic solvent or the like, so that the metal film formed on the resist pattern is eliminated with the resist pattern by lift-off. Thereby, it is possible to form the source electrode 42 and the drain electrode 43 that are formed of Ti/Al, on the electron supply layer 13 in an area where no resist pattern has been formed. Subsequently, a heat treatment is conducted at a temperature of about 600° C., and thereby, it is possible to provide ohmic contact between the source electrode 42 and the drain electrode 43.

Then, as illustrated in FIG. 6A, an insulation film 30 is formed that has an opening 30a. The insulation film 30 is formed of a material such as an oxide, a nitride, or the like, that has an insulation property, for example, such as SiN or SiO₂. In the present embodiment, the insulation film 30 is formed of SiN. Specifically, after a SiN film that provides the insulation film 30 is film-formed by an atomic layer deposition (ALD) method, a photoresist is applied onto a surface of the SiN film and light exposure and development thereof is conducted by a light exposure device. Thereby, a non-illustrated resist pattern is formed that has an aperture in an area for forming the opening 30a, that is, an area directly below an area for forming a gate electrode 41 described below. Subsequently, a SiN film that is exposed at the aperture of the resist pattern is eliminated by wet etching until a surface of the electron supply layer 13 is exposed, so that the opening 30a is formed. Thus, the insulation film 30 having the opening 30a is formed in an area directly below an area for forming the gate electrode 41. Subsequently, the non-illustrated resist pattern is eliminated by an organic solvent or the like. In the present embodiment, elimination of SiN at a time when the opening 30a is formed is conducted by wet etching, and hence, the electron supply layer is rarely damaged. Here, in dry etching, an etching gas for eliminating SiN is different from a preferable etching gas for eliminating AlGaN. Therefore, an etching gas is selected in dry etching, and thereby, it is possible to eliminate the entirety of SiN in an area for forming the opening 30a while the electron supply layer 13 is rarely damaged.

Then, as illustrated in FIG. 6B, a first insulation film 31 is formed on the electron supply layer 13 and the insulation film 30 that are exposed at the opening 30a. The first insulation layer 31 is formed by a film formation method such as an ALD method to film-form about 5 nm of a SiO₂ film.

Then, as illustrated in FIG. 6C, a second insulation layer 32 is formed on the first insulation layer 31. The second insulation layer 32 is formed by a film formation method such as an ALD method to film-form about 30 nm of an Al₂O₃ film. Here, for a film formation method for the first insulation layer 31 and the second insulation layer 32, film formation may be conducted by a film formation method other than an ALD method. Furthermore, a heat treatment may be conducted after the second insulation layer 32 is formed. This heat treatment may be conducted, for example, in an oxygen atmosphere or a nitrogen atmosphere at a temperature of 600° C. for one minute. It is possible to move oxygen ions from the second insulation layer 32 to the first insulation layer 31 more certainly by conducting this heat treatment, and hence, it is possible to produce a dipole in the first insulation layer 31 and the second insulation layer 32 more certainly. Thereby, it is possible to eliminate 2DEG in an area directly below the gate electrode 41, that is, an area of the insulation film 30 directly below the opening 30a, more certainly, and it is possible to attain normally off more certainly.

Then, as illustrated in FIG. 7A, a gate electrode 41 is formed on the second insulation layer 32 in an area where the opening 30a has been formed. Specifically, a photoresist is applied onto the second insulation layer 32 and light exposure and development thereof are conducted by a light exposure device, so that a non-illustrated resist pattern is formed that has an aperture in an area for forming the gate electrode 41. This resist pattern is formed in such a manner that the aperture of the resist pattern is located in an area that includes the opening 30a in the insulation film 30. Subsequently, a laminated metal film of Ni/Au is film-formed by vacuum deposition or the like and dipped in an organic solvent or the like, and thereby, the metal film formed on the resist pattern is eliminated with the resist pattern by lift-off. Thereby, it is possible to form the gate electrode 41 formed of Ni/Au on the second insulation layer 32 in an area where no resist pattern has been formed. Here, in the present embodiment, “directly below the gate electrode 41” refers to an area under the second insulation layer 32 and the first insulation layer 31, or an area under the second insulation layer 32, the first insulation layer 31, and the electron supply layer 13, and the like.

Then, as illustrated in FIG. 7B, a protection insulation film 33 is formed on the second insulation layer 32 or the like based on a material such as SiN or SiO₂ by an ALD method, a CVD method, or the like.

As described above, it is possible to fabricate a semiconductor device according to the present embodiment. In the present embodiment, it is possible to obtain a normally-off semiconductor device while a semiconductor layer such as the electron supply layer 13 is not damaged by etching or the like. Furthermore, because a heat treatment is conducted according to need after the first insulation layer 31 and the second insulation layer 32 are laminated and formed, it is possible to attain normally off, so that fabrication thereof is easy and the uniformity of a fabricated semiconductor device is also high. Hence, in the present embodiment, it is possible to fabricate a semiconductor device at a high yield and a low cost.

Here, the electron supply layer 13 may be formed of InAlGaN, InAlN, or the like, as well as AlGaN. Furthermore, an AlN layer may be formed between the electron supply layer 13 formed of AlGaN and the electron transit layer 12 formed of GaN.

### Second Embodiment

### Semiconductor Device

Next, a semiconductor device according to a second embodiment will be described based on FIG. 8.

A semiconductor device according to the present embodiment is such that an electron transit layer 12 formed of i-GaN and an electron supply layer 13 formed of AlGaN are laminated and formed on a substrate 11. An inter-element separation area 21 is formed on a part of the electron supply layer 13 and the electron transit layer 12. An insulation film 30 is formed on the electron supply layer 13 in an area other than an area for forming a source electrode 42 and a drain electrode 43. Here, a part of the insulation film 30 and the electron supply layer 13 is eliminated in an area for forming a gate electrode 41 to form an opening 130a. The opening 130a may be provided by eliminating the entirety of the electron supply layer 13 in an area for forming the gate electrode 41, and further, may be provided by eliminating a part of the electron transit layer 12.

Furthermore, a first insulation layer 31 and a second insulation layer 32 are laminated and formed on the electron supply layer 13 or the like and the insulation film 30 at the opening 130a. Furthermore, the gate electrode 41 is formed on the second insulation layer 32 in an area where the opening 130a has been formed, and the source electrode 42 and the drain electrode 43 are formed on the electron supply layer 13. Furthermore, a protection insulation film 33 is formed on the second insulation layer 32 or the like.

Although 2DEG 12a is produced in the electron transit layer 12 and near an interface between the electron transit layer 12 and the electron supply layer 13 in the present embodiment, the 2DEG 12a is eliminated directly below the gate electrode 41 for the reason described below. Thus, the 2DEG 12a is eliminated directly below the gate electrode 41, and thereby, it is possible to attain normally off.

In the present embodiment, the first insulation layer 31 and the second insulation layer 32 are formed of mutually different oxides. Specifically, the first insulation layer 31 is formed of a material that includes SiO₂, HfO₂, or the like. In the case where the first insulation layer 31 is formed of a material that includes SiO₂, the second insulation layer 32 is formed of a material that includes one or more selected from Al₂O₂, ZrO₂, Ta₂O₅, Ga₂O₂, HfO₂, and the like.

Furthermore, in the case where the first insulation layer 31 is formed of a material that includes HfO₂, the second insulation layer 32 is formed of a material that includes one or more selected from Al₂O₃, ZrO₂, Ta₂O₅, Ga₂O₃, and the like.

Here, in the case where the first insulation layer 31 is formed of a material that includes SiO₂, it is preferable for the second insulation layer 32 to be formed of a material that includes Al₂O₂ or HfO₂. Furthermore, in the case where the first insulation layer 31 is formed of a material that includes HfO₂, it is preferable for the second insulation layer 32 to be formed of a material that includes Al₂O₂.

Furthermore, the insulation film 30 is formed of an oxide or a nitride, and specifically, is formed of a material that includes SiO₂, SiN, or the like. In the present embodiment, the insulation film 30 is formed of SiN. Here, the insulation film 30 in the present embodiment may be described as a third insulation layer.

Furthermore, the protection insulation film 33 is formed of an insulation material such as an oxide or a nitride, and specifically, is formed of a material that includes SiO₂, SiN, or the like.

In the present embodiment, the electron supply layer 13 or the like is eliminated in an area directly below the gate electrode 41 to form a recess, and hence, it is possible to attain normally off even more certainly.

(Fabrication Method of a Semiconductor Device)

Next, a fabrication method of a semiconductor device in the present embodiment will be described based on FIG. 9A, FIG. 9B, FIG. 9C, FIG. 10A, FIG. 10B, FIG. 10C, FIG. 11A, and FIG. 11B.

First, as illustrated in FIG. 9A, a non-illustrated buffer layer that provides a semiconductor layer, an electron transit layer 12, and an electron supply layer 13 are epitaxially grown and formed in order on a substrate 11 based on an MOVPE method. Here, a structure with a cap layer formed on the electron supply layer 13 may be provided according to need. It is possible to form the cap layer based on, for example, n-GaN doped with an impurity element such as Si.

For the substrate 11, it is possible to use a substrate of Si, sapphire, SiC, GaN, AlN, or the like.

The electron transit layer 12 is a layer that provides a first semiconductor layer and is made of intentionally undoped GaN with a thickness of about 3 μm.

The electron supply layer 13 is a layer that provides a second semiconductor layer and is made of intentionally undoped Al_{0.25}Ga_{0.75}N with a thickness of about 20 nm. Here, n-type doped with an impurity element such as Si may be used for the electron supply layer 13. Thereby, 2DEG 12a is produced in the electron transit layer 12 and near an interface between the electron transit layer 12 and the electron supply layer 13.

For MOVPE in the present embodiment, trimethylgallium (TMG) as a raw material gas for Ga, trimethylaluminum (TMA) as a raw material for Al, and ammonia (NH₃) as a raw material for N are used, while monosilane (SiH₄) or the like as a raw material for Si is used. Here, these raw material gases are supplied to a reactor of an MOVPE device while hydrogen (H₂) is a carrier gas.

Then, as illustrated in FIG. 9B, an inter-element separation area 21 is formed on the formed semiconductor layer. Specifically, a photoresist is applied onto the electron supply layer 13 and light exposure and development thereof are conducted by a light exposure device, so that a non-illustrated resist pattern is formed that has an aperture in an area for forming the inter-element separation area 21. Subsequently, the inter-element separation area 21 is formed by dry etching using a chlorine-based gas or an ion implantation method. After the inter-element separation area 21 is formed, the resist pattern is eliminated by an organic solvent or the like.

Then, as illustrated in FIG. 9C, a source electrode 42 and a drain electrode 43 are formed that contact a semiconductor layer such as the electron supply layer 13. Specifically, a photoresist is applied onto the electron supply layer 13 and light exposure and development thereof are conducted by a light exposure device, so that a non-illustrated resist pattern is formed that has an aperture in an area for forming the source electrode 42 and the drain electrode 43. Subsequently, a laminated metal film of Ti/Al is film-formed by vacuum deposition and dipped in an organic solvent or the like, so that the metal film formed on the resist pattern is eliminated with the resist pattern by lift-off. Thereby, it is possible to form the source electrode 42 and the drain electrode 43 that are formed of Ti/Al, on the electron supply layer 13 in an area where no resist pattern has been formed. Subsequently, a heat treatment is conducted at a temperature of about 600° C., and thereby, it is possible to provide ohmic contact between the source electrode 42 and the drain electrode 43.

Then, as illustrated in FIG. 10A, an insulation film 30 is formed and an opening 130a is formed by eliminating a part of the insulation film 30 and the electron supply layer 13 in an area directly below an area for forming a gate electrode 41. The insulation film 30 is formed of a material such as an oxide, a nitride, or the like, that has an insulation property, for example, such as SiN or SiO₂. In the present embodiment, the insulation film 30 is formed of SiN. Specifically, after a SiN film that provides the insulation film 30 is film-formed by an atomic layer deposition method, a photoresist is applied onto a surface of the SiN film and light exposure and development thereof is conducted by a light exposure device. Thereby, a non-illustrated resist pattern is formed that has an aperture in an area for forming the opening 130a, that is, an area directly below an area for forming a gate electrode 41 described below. Subsequently, a SiN film that is exposed at the aperture of the resist pattern is eliminated by wet etching and further a part of the electron supply layer 13 is eliminated by fry etching using a fluorine-based gas, so that the opening 130a is formed. Here, the opening 130a may be such that the entirety of the electron supply layer 13 is eliminated and the electron transit layer 12 is exposed, as well as the case where a part of the electron supply layer 13 is eliminated, and further, a part of the electron transit layer 12 may be eliminated. Subsequently, the non-illustrated resist pattern is eliminated by an organic solvent or the like. Furthermore, dry etching may be conducted instead of wet etching, in the case where a SiN film that is exposed at the aperture of the resist pattern is eliminated.

Then, as illustrated in FIG. 10B, a first insulation layer 31 is formed on the electron supply layer 13 and the insulation film 30 that are exposed at the opening 130a. The first insulation layer 31 is formed by a film formation method such as an ALD method to film-form about 5 nm of a SiO₂ film.

Then, as illustrated in FIG. 10C, a second insulation layer 32 is formed on the first insulation layer 31. The second insulation layer 32 is formed by a film formation method such as an ALD method to film-form about 30 nm of an Al₂O₃ film. Here, for a film formation method for the first insulation layer 31 and the second insulation layer 32, film formation may be conducted by a film formation method other than an ALD method. Furthermore, a heat treatment may be conducted after the second insulation layer 32 is formed. This heat treatment may be conducted, for example, in an oxygen atmosphere or a nitrogen atmosphere at a temperature of 600° C. for one minute. It is possible to move oxygen ions from the second insulation layer 32 to the first insulation layer 31 more certainly by conducting this heat treatment, and hence, it is possible to produce a dipole in the first insulation layer 31 and the second insulation layer 32 more certainly. Thereby, it is possible to eliminate 2DEG in an area directly below the gate electrode 41, that is, an area directly below the opening 130a, more certainly, and it is possible to attain normally off more certainly.

Then, as illustrated in FIG. 11A, a gate electrode 41 is formed on the second insulation layer 32 in an area where the opening 130a has been formed. Specifically, a photoresist is applied onto the second insulation layer 32 and light exposure and development thereof are conducted by a light exposure device, so that a non-illustrated resist pattern is formed that has an aperture in an area for forming the gate electrode 41. This resist pattern is formed in such a manner that the aperture of the resist pattern is located in an area that includes the opening 130a. Subsequently, a laminated metal film of Ni/Au is film-formed by vacuum deposition or the like and dipped in an organic solvent or the like, and thereby, the metal film formed on the resist pattern is eliminated with the resist pattern by lift-off. Thereby, it is possible to form the gate electrode 41 formed of Ni/Au on the second insulation layer 32 in an area where no resist pattern has been formed. Here, in the present embodiment, “directly below the gate electrode 41” refers to an area under the second insulation layer 32 and the first insulation layer 31, or an area under the second insulation layer 32, the first insulation layer 31, and the electron supply layer 13, and the like.

Then, as illustrated in FIG. 11B, a protection insulation film 33 is formed on the second insulation layer 32 or the like based on a material such as SiN or SiO₂ by an ALD method, a CVD method, or the like.

As described above, it is possible to fabricate a semiconductor device according to the present embodiment. In the present embodiment, a part of the electron supply layer 13 directly below the gate electrode 41 is eliminated, so that it is possible to further eliminate 2DEG 12a directly below the gate electrode 41 and it is possible to attain normally-off even more certainly.

Here, the contents other than those described above are similar to those of the first embodiment.

### Third Embodiment

Next, a third embodiment will be described. The present embodiment has a structure similar to that of the first embodiment and a first insulation layer is formed of HfO₂. Specifically, as illustrated in FIG. 12, a semiconductor device is such that a film of HfO₂ with a thickness of about 5 nm is formed to form a first insulation layer 231. In the present embodiment, it is also possible to provide a normally off semiconductor device readily, similarly to the first embodiment. Here, the contents other than those described above are similar to those of the first embodiment.

### Fourth Embodiment

Next, a fourth embodiment will be described. As illustrated in FIG. 13, a structure of the present embodiment is such that a first insulation layer 31 and a second insulation layer 32 are formed on an electron supply layer 13 that is directly below a gate electrode 41.

A fabrication method of such a semiconductor device is such that, for example, a first insulation layer 31 and a second insulation layer 32 are film-formed by a film formation method, a film formation condition, or the like, with a low step coverage, in a process illustrated in FIG. 6B and FIG. 6C in the fabrication method of a semiconductor device according to the first embodiment. Subsequently, it is possible to conduct formation thereof by eliminating the first insulation layer 31 and the second insulation layer 32 on an insulation film 30 and conducting a process similar to the process illustrated in FIG. 7A. Furthermore, formation thereof may be conducted by film-forming the first insulation layer 31 and the second insulation layer 32 and eliminating the first insulation layer 31 and the second insulation layer 32 in an area other than an area for forming the gate electrode 41 before the insulation film 30 is film-formed. Here, the contents other than those described above are similar to those of the first embodiment, and further, it is also possible to apply the present embodiment to the second embodiment.

### Fifth Embodiment

Next, a fifth embodiment will be described. The present embodiment is such that the insulation film 30 and the first insulation layer 31 in the first embodiment or the like are formed of an identical material. Specifically, as illustrated in FIG. 14, a structure is formed by a first insulation layer 331 that corresponds to the insulation film 30 and the first insulation layer 31.

In the present embodiment, the first insulation layer 331 is formed of a material similar to that of the first insulation layer 31 in the first embodiment, and an opening 331a is formed in an area for forming a gate electrode 41 by eliminating a part of the first insulation layer 331. Therefore, the first insulation layer 331 at the opening 331a is formed to be thinner than another area where the opening 331a is not formed.

It is possible to fabricate a semiconductor device according to the present embodiment by forming a SiO₂ film for forming the first insulation layer 331 and subsequently etching the SiO₂ film in an area for forming the gate electrode 41 to a desired depth to form the opening 331a. Thereby, it is possible to conduct processes illustrated in FIG. 6A and FIG. 6B similarly in a fabrication method of a semiconductor device according to the first embodiment, and it is possible to further reduce a fabrication process. Furthermore, when the opening 331a is formed, the electron supply layer 13 or the like is not exposed to an etching gas or an etching fluid, and hence, it is possible to further suppress damage applied on a semiconductor layer in the electron supply layer 13 or the like. Here, the contents other than those described above are similar to those of the first embodiment, and further, it is also possible to apply the present embodiment to the second embodiment.

### Sixth Embodiment

Next, a sixth embodiment will be described. The present embodiment is for a semiconductor device, a power supply device, and a high-frequency amplifier.

A semiconductor device in the present embodiment is such that one of semiconductor devices in the first to fifth embodiments is discretely packaged, wherein a thus discretely packaged semiconductor device will be described based on FIG. 15. Additionally, FIG. 15 schematically illustrates an inside of the discretely packaged semiconductor device, wherein arrangement of electrodes or the like is different from those illustrated in the first to fifth embodiments.

First, a semiconductor device fabricated in the first to fifth embodiments is cut by dicing or the like to form a semiconductor chip 410 that is an HEMT of a GaN-based semiconductor material. This semiconductor chip 410 is fixed on a lead frame 420 by a die-attaching agent 430 such as solder. Here, this semiconductor chip 410 corresponds to the semiconductor device in the first to fifth embodiments.

Then, a gate electrode 441 is connected to a gate lead 421 by a bonding wire 431, while a source electrode 442 is connected to a source lead 422 by a bonding wire 432 and a drain electrode 443 is connected to a drain lead 423 by a bonding wire 433. Here, the bonding wires 431, 432, and 433 are formed of a metal material such as Al. Furthermore, the gate electrode 441 in the present embodiment is a gate electrode pad that is connected to the gate electrode 41 of the semiconductor device in the first to fifth embodiments. Furthermore, the source electrode 442 is a source electrode pad that is connected to the source electrode 42 of the semiconductor device in the first to fifth embodiments. Furthermore, the drain electrode 443 is a drain electrode pad that is connected to the drain electrode 43 of the semiconductor device in the first to fifth embodiments.

Then, plastic sealing with a molded resin 440 is conducted by a transfer molding method. Thus, it is possible to fabricate a discretely packaged semiconductor device that is an HEMT using a GaN-based semiconductor material.

Next, a power supply device and a high-frequency amplifier in the present embodiment will be described. The power supply device and the high-frequency amplifier in the present embodiment are a power supply device and a high-frequency amplifier using one of the semiconductor devices in the first to fifth embodiments.

First, a power supply device in the present embodiment will be described based on FIG. 16. A power supply device 460 in the present embodiment includes a primary circuit 461 at a high voltage, a secondary circuit 462 at a low voltage, and a transformer 463 arranged between the primary circuit 461 and the second circuit 462. The primary circuit 461 includes an alternating current power supply 464, a so-called bridge rectifier circuit 465, a plurality of (four, in an example illustrated in FIG. 16) switching elements 466, one switching element 467, and the like. The secondary circuit 462 includes a plurality of (three, in an example illustrated in FIG. 16) switching elements 468. In an example illustrated in FIG. 16, semiconductor devices in the first to fifth embodiments are used as switching elements 466 and 467 of the primary circuit 461. Here, it is preferable for the switching elements 466 and 467 of the primary circuit 461 to be normally-off type semiconductor devices. Furthermore, a normal metal insulator semiconductor field effect transistor (MISFET) formed of silicon is used for the switching elements 468 used in the secondary circuit 462.

Next, a high-frequency amplifier in the present embodiment will be described based on FIG. 17. A high-frequency amplifier 470 in the present embodiment may be applied to, for example, a power amplifier for a base station of a mobile phone network. This high-frequency amplifier 470 includes a digital pre-distortion circuit 471, mixers 472, a power amplifier 473, and a directional coupler 474. The digital pre-distortion circuit 471 compensates for nonlinear distortion of an input signal. The mixer 472 mixes an input signal compensated for nonlinear distortion with an alternating current signal. The power amplifier 473 amplifies the input signal mixed with the alternating current signal. In an example illustrated in FIG. 17, the power amplifier 473 has one of semiconductor devices in the first to fifth embodiments. The directional coupler 474 conducts monitoring of an input signal or an output signal, or the like. In a circuit illustrated in FIG. 17, for example, it is possible for the mixer 472 to mix an output signal with an alternating current signal to be transmitted to the digital pre-distortion circuit 471, due to switching of a switch.

For a disclosed semiconductor device, it is possible to be fabricated readily, it is possible to provide high uniformity, and it is possible to conduct a normally off operation in a semiconductor device such as a field-effect transistor using a nitride semiconductor such as GaN as a semiconductor material.

All examples and conditional language provided herein are intended for the pedagogical purposes of aiding the reader in understanding the invention and the concepts contributed by the inventor to further the art, and are not to be construed as limitations to such specially recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor device, comprising:
a substrate;
a first semiconductor layer formed on the substrate;
a second semiconductor layer formed on the first semiconductor layer;
a first insulation layer formed on the second semiconductor layer, the first insulation layer being formed of a material that includes SiO₂;
a second insulation layer formed on the first insulation layer, the second insulation film being formed of a material that includes one or more selected from Al₂O₃, ZrO₂, Ta₂O₅, Ga₂O₃, and HfO₂; and
a gate electrode formed on the second insulation layer.

2. The semiconductor device as claimed in claim 1, wherein the second insulation layer is formed of a material that includes Al₂O₃ or HfO₂.

3. A semiconductor device, comprising:
a substrate;
a first semiconductor layer formed on the substrate;
a second semiconductor layer formed on the first semiconductor layer;
a first insulation layer formed on the second semiconductor layer, the first insulation layer being formed of a material that includes HfO₂;
a second insulation layer formed on the first insulation layer, the second insulation layer being formed of a material that includes one or more selected from Al₂O₃, ZrO₂, Ta₂O₅, and Ga₂O₃; and
a gate electrode formed on the second insulation layer.

4. The semiconductor device as claimed in claim 3, wherein the second insulation layer is formed of a material that includes Al₂O₃.

5. The semiconductor device as claimed in claim 1, wherein a thickness of the first insulation layer in an area configured to form the gate electrode is 30 nm or less.

6. The semiconductor device as claimed in claim 5, wherein a thickness of the first insulation layer in an area configured to form the gate electrode is 2 nm or more.

7. The semiconductor device as claimed in claim 1, wherein a third insulation layer having an opening in an area configured to form the gate electrode is formed on the second semiconductor layer and the first insulation layer and the second insulation layer are formed on the second semiconductor layer at the opening.

8. The semiconductor device as claimed in claim 1, wherein a third insulation layer is formed on the second semiconductor layer, an opening is formed by removing a part of the third insulation layer and the second semiconductor layer in an area configured to form the gate electrode, and the first insulation layer and the second insulation layer are formed on the second semiconductor layer at the opening.

9. The semiconductor device as claimed in claim 1, wherein a third insulation layer is formed on the second semiconductor layer, an opening is formed by removing the third insulation layer, the second semiconductor layer, and the first semiconductor layer, or removing a part of the third insulation layer, the second semiconductor layer, and the first semiconductor layer, in an area configured to form the gate electrode, and the first insulation layer and the second insulation layer are formed on the first semiconductor layer at the opening.

10. The semiconductor device as claimed in claim 1, wherein an opening is formed on the first insulation layer by removing a part of the first insulation layer in an area configured to form the gate electrode and the second insulation layer is formed on the first insulation layer at the opening.

11. The semiconductor device as claimed in claim 7, wherein the third insulation layer is formed of a material that includes SiN or SiO₂.

12. The semiconductor device as claimed in claim 1, wherein a source electrode and a drain electrode are provided to contact the second semiconductor layer.

13. The semiconductor device as claimed in claim 1, wherein the first semiconductor layer and the second semiconductor layer are formed of a nitride semiconductor.

14. The semiconductor device as claimed in claim 1, wherein the first semiconductor layer is formed of a material that includes GaN.

15. The semiconductor device as claimed in claim 1, wherein the second semiconductor layer is formed of a material that includes one of AlGaN, InAlN, and InAlGaN.

16. A power supply device, comprising the semiconductor device as claimed in claim 1.

17. An amplifier, comprising the semiconductor device as claimed in claim 1.
